(19) United States
(12) Patent Application Publication
(10) Pub. No.: US 2013/0161737 A1
(43) Pub. Date: Jun. 27, 2013

(54) SEMICONDUCTOR DEVICE AND METHOD OF MANUFACTURING THE SAME

(71) Applicants: Jaehoon PARK, Suwon (KR); Dong Soo SEO, Suwon (KR)

(72) Inventors: Jaehoon PARK, Suwon (KR); Dong Soo SEO, Suwon (KR)

(73) Assignee: SAMSUNG ELECTRO-MECHANICS CO., LTD

(21) Appl. No.: 13/620,518

(22) Filed: Sep. 14, 2012

(30) Foreign Application Priority Data
Dec. 26, 2011 (KR) 10-2011-0141939

(51) Int. Cl. H01L 29/78; H01L 21/336

(52) U.S. Cl. 257/330; 438/270; 257/E29.262; 257/E21.41

(57) ABSTRACT

There are provided a semiconductor device and a method of manufacturing the same, capable of removing a shoot-through phenomenon by forming capacitance between an electrode and a lateral surface of a protrusion region of a gate and increasing a gate-source capacitance. The semiconductor device may include: a semiconductor body having a predetermined volume; a source formed on an upper surface of the semiconductor body; a gate formed in a groove of the semiconductor body and having a protrusion region protruded upwardly of the upper surface of the semiconductor body, the groove having a predetermined depth and the protrusion region having a protrusion height altered depending on a level of capacitance to be set; and an electrode electrically connected to the source to form capacitance together with a lateral surface of the protrusion region of the gate.

### CROSS-REFERENCE TO RELATED APPLICATIONS

This application claims the priority of Korean Patent Application No. 10-2011-0141939 filed on Dec. 26, 2011, in the Korean Intellectual Property Office, the disclosure of which is incorporated herein by reference.

### BACKGROUND OF THE INVENTION

1. Field of the Invention

The present invention relates to a semiconductor device resistant to shoot-through, which may be generated in a power supply device, and a method of manufacturing the same.

2. Description of the Related Art

In general, electronic devices meeting various user requirements are being implemented using various schemes, and these electronic devices may include a power supply device for supplying operating power in order to implement various device functions.

A power supply device may generally employ a switching mode power supply type due to advantages thereof in terms of power conversion efficiency, miniaturization, and the like.

FIG. 1 is a schematic circuit diagram of a general power supply device.

Referring to FIG. 1, a general power supply device 10 may include first and second switches HS and LS alternately switching an input power, and an integrated circuit (IC) controlling the switching of the first and second switches.

This general power supply device may have a shoot-through problem in a case in which a synchronous buck converter is employed therewith.

Here, the shoot-through problem may be solved by compulsorily assigning a dead time between alternating switching periods of the first and second switches HS and LS.

However, it maybe difficult to solve the shoot-through problem in the case in which an abrupt voltage change (dV/dt) occurs at a contact point of the first switch HS and the second switch LS.

In other words, when an abrupt voltage change (dV/dt) occurs at a contact point of the first switch HS and the second switch LS, a large displacement current (i) flows to a gate terminal of the second switch LS through a gate-drain capacitance component (Cgd) of the second switch LS. Here, a part (i1) of the displacement current (i) flows to a circuit in which a gate resistance component (Rg), a gate inductance component (Lg), and an external resistor (Rext) are series connected, and then flows out to the ground, and the other part (i2) of the displacement current (i) flows out to the ground through a gate-source capacitance component (Cgs) of the second switch (LS).

A residual component of the part (i1) of the displacement current induces potential drop to the gate resistance component (Rg) and the external resistor (next). Here, when this potential drop is larger than a threshold voltage of the second switch LS, the second switch is turned on, and thus, there occurs a shoot-through phenomenon in which the second switch LS is simultaneously turned on together with the previously turned-on first switch HS.

Therefore, a gate-source capacitance component of a switch is required to be increased, which causes an increase in a volume of the switch. However, it may be difficult to manufacture a desired number of switches on a semiconductor substrate having a limited area.

### SUMMARY OF THE INVENTION

An aspect of the present invention provides a semiconductor device capable of removing a shoot-through phenomenon by forming capacitance between an electrode connected to a source and a lateral surface of a protrusion region of a gate and increasing gate-source capacitance, and a method of manufacturing the same.

According to an aspect of the present invention, there is provided a semiconductor device, including: a semiconductor body having a predetermined volume; a source formed on an upper surface of the semiconductor body; a gate formed in a groove of the semiconductor body and having a protrusion region protruded upwardly of the upper surface of the semiconductor body, the groove having a predetermined depth and the protrusion region having a protrusion height altered depending on a level of capacitance to be set; and an electrode electrically connected to the source to form capacitance together with a lateral surface of the protrusion region of the gate.

The semiconductor device may further include a drain formed on a lower surface of the semiconductor body.

The semiconductor device may further include a dielectric layer formed between the protrusion region of the gate and the electrode.

The source, the drain, and the gate may constitute a metal-oxide-semiconductor field-effect transistor (MOS FET).

The protrusion height of the protrusion region of the gate may be at least 0.5 times greater than a width thereof.

According to another aspect of the present invention, there is provided a method of manufacturing a semiconductor device, the method including: preparing a semiconductor body having a predetermined volume, a source formed on an upper surface of the semiconductor body, a gate formed in a groove of the semiconductor body and having a protrusion region protruded upwardly of the upper surface of the semiconductor body, the groove having a predetermined depth, and an electrode covering the protrusion region of the gate; grinding and removing a portion of the electrode disposed to cover an upper surface of the protrusion region of the gate; and depositing an oxide film on the upper surface of the protrusion region of the gate.

The preparing of the electrode may include setting a desired capacitance level by altering a protrusion height of the protrusion region of the gate and a length of the electrode facing a lateral surface of the protrusion region.

The preparing of the electrode may include forming a drain on a lower surface of the semiconductor body.

The preparing of the electrode may include electrically connecting the electrode to the source.

The preparing of the electrode may include forming a dielectric layer between the protrusion region of the gate and the electrode.

The source, the drain, and the gate may constitute a metal-oxide-semiconductor field-effect transistor (MOS FET).

The protrusion height of the protrusion region of the gate may be at least 0.5 times greater than a width thereof.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic circuit diagram of a general power supply device;

FIG. 2 is a switching waveform graph of the power supply device of FIG. 1;

FIG. 3 is a switching waveform graph of the power supply device of FIG. 1 due to abrupt voltage change;

FIG. 4 is an equivalent circuit diagram including a parasitic capacitance of a switching semiconductor device, employed in the power supply device of FIG. 1, due to the abrupt voltage change of FIG. 3;

FIG. 5 is a schematic view of a semiconductor device according to an embodiment of the present invention;

FIG. 6 shows a method of manufacturing a semiconductor device according to an embodiment of the present invention;

FIG. 7 shows a problem that may occur at the time of manufacturing a semiconductor device; and

FIG. 8 is a partial enlarged view of a semiconductor device according to an embodiment of the present invention.

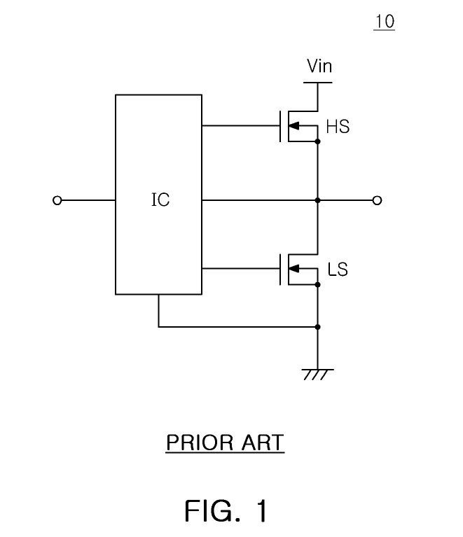

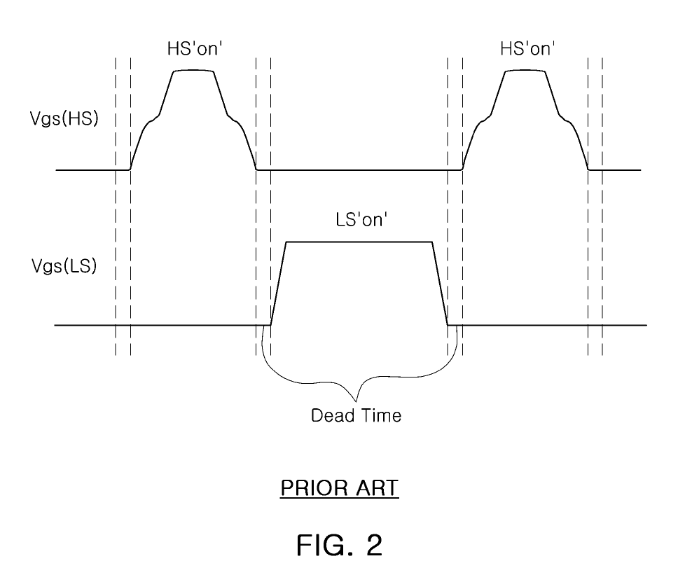

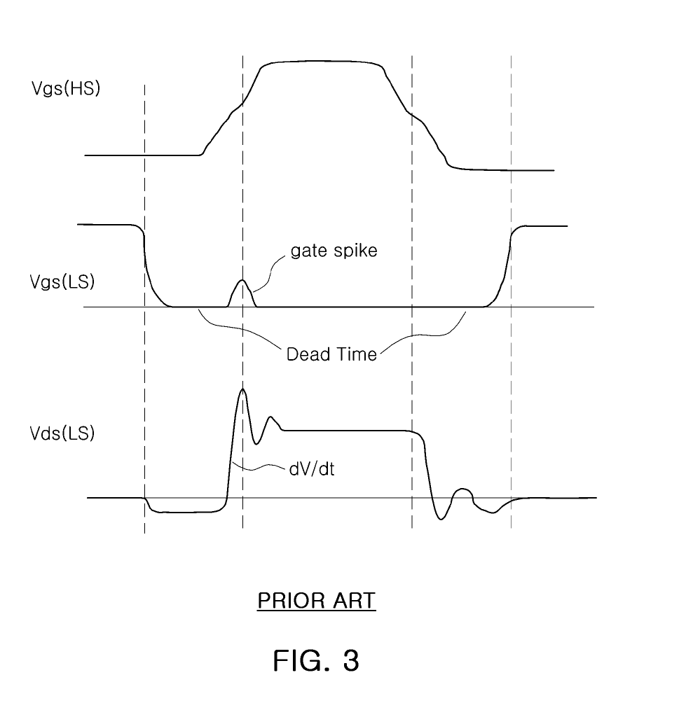

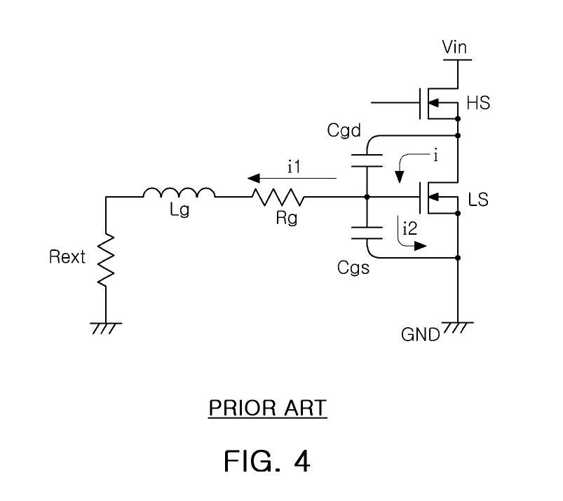

### DETAILED DESCRIPTION OF THE EMBODIMENTS

Hereinafter, embodiments will be described in detail with reference to the accompanying drawings so that they can be easily practiced by those skilled in the art to which the present invention pertains.

However, detailed descriptions related to well-known functions or configurations will be ruled out in order not to unnecessarily obscure subject matters of the present invention.

In addition, like reference numerals will be used to describe elements having the same or similar functions throughout the accompanying drawings.

Throughout this specification, it will be understood that when an element is referred to as being “connected to” another element, it can be directly connected to the other element or may be indirectly connected to the other element with element(s) interposed therebetween.

In addition, unless explicitly described to the contrary, the word “comprise” and variations such as “comprises” or “comprising,” will be understood to imply the inclusion of stated elements but not the exclusion of any other elements.

Hereinafter, embodiments of the present invention will be described in detail with reference to the accompanying drawings.

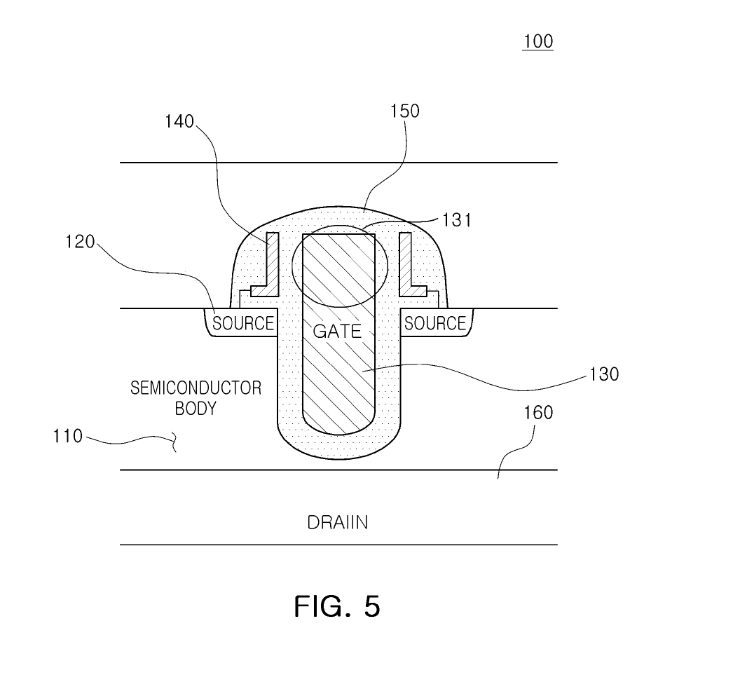

FIG. 5 schematically shows the configuration of a semiconductor device according to an embodiment of the present invention.

Referring to FIG. 5, a semiconductor device 100 according to an embodiment of the present invention may include a semiconductor body 110, a source 120, a gate 130, an electrode 140, a dielectric layer 150, and a drain 160.

The semiconductor body 110 may have a predetermined volume, and form a body of the semiconductor device 100. The semiconductor body 110 may have a groove formed in a part thereof, the groove having a predetermined depth. In a case in which the semiconductor device 100 is an N-type metal-oxide-semiconductor field-effect transistor (MOS FET), the semiconductor body 110 may be formed of a P-type impurity.

The source 120 may be formed on an upper surface of the semiconductor body 110 to be disposed on an upper surface around the groove formed in the semiconductor body 110. In the case in which the semiconductor device 100 is an N-type MOS FET, the source 120 may be formed of an N-type impurity.

The gate 130 may be formed in the groove of the semiconductor body 110, and at least a part of the gate 130 may be a protrusion region protruded from an inside of the groove upwardly of the upper surface of the semiconductor body 110. A height of the protrusion region 131 may be altered depending on a desired level of capacitance to be set. In general, the gate 130 may be formed of a conductor material such as poly-silicon or the like.

The electrode 140 may be provided to face a lateral surface of the protrusion region 131 of the gate 130, and may be electrically connected to the source 120 to form capacitance together with the lateral surface of the protrusion 131 of the gate 130. The electrode may be formed of a conductor material such as poly-silicon or the like. In order to form the capacitance between the electrode 140 and the lateral surface of the protrusion region 131 of the gate 130, the dielectric layer 150 may be formed between the electrode 140 and the protrusion region 131 of the gate 130. FIG. 5 shows that the electrode 140 and the source 120 are electrically connected to each other inside the semiconductor device. However, without being limited thereto, the electrode 140 and the source 120 may be electrically connected to each other by various methods such as surface contact and the like, outside or inside the semiconductor device.

The drain 160 may be formed on a lower surface of the semiconductor body 110. In the case in which the semiconductor device 100 is an N-type MOS FET, the drain 160 may be formed of an N-type impurity.

The semiconductor device 100 having the source 120, the gate 130, and the drain 160 may be a metal-oxide-semiconductor field-effect transistor (MOS FET).

As such, the impurities for the semiconductor body 110, the source 120, and the drain 160 have been described in the case in which the semiconductor device 100 is an N-type MOS FET. However, in a case in which the semiconductor device 100 is a P-type MOS FET, impurities for the semiconductor body 110, the source 120, and the drain 160 may be contrary to those in the case in which the semiconductor device 100 is the N-type MOS FET.

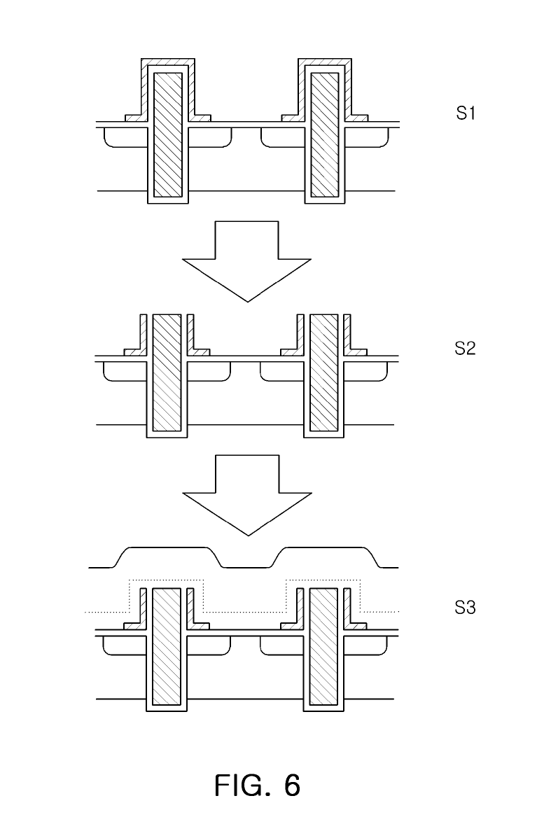

FIG. 6 schematically shows a method of manufacturing the semiconductor device according to an embodiment of the present invention.

Referring to FIGS. 5 and 6, there may be prepared the semiconductor body 110 having a predetermined volume; the source 120 formed on the upper surface of the semiconductor body 110; the gate 130 formed in the groove of the semiconductor body 120, which has a predetermined depth, and having the protrusion region 131 protruded upwardly of the upper surface of the semiconductor body 110; and the electrode 140 covering the protrusion region 131 of the gate 130 (S1).

Then, a portion of the electrode 140 disposed to cover an upper surface of the protrusion region 131 of the gate 130, may be removed by grinding (S2).

Finally, an oxide film may be oxide-deposited (S3). The oxide film may be formed on upper surfaces of the protrusion region 131 of the gate 130 and the electrode 140.

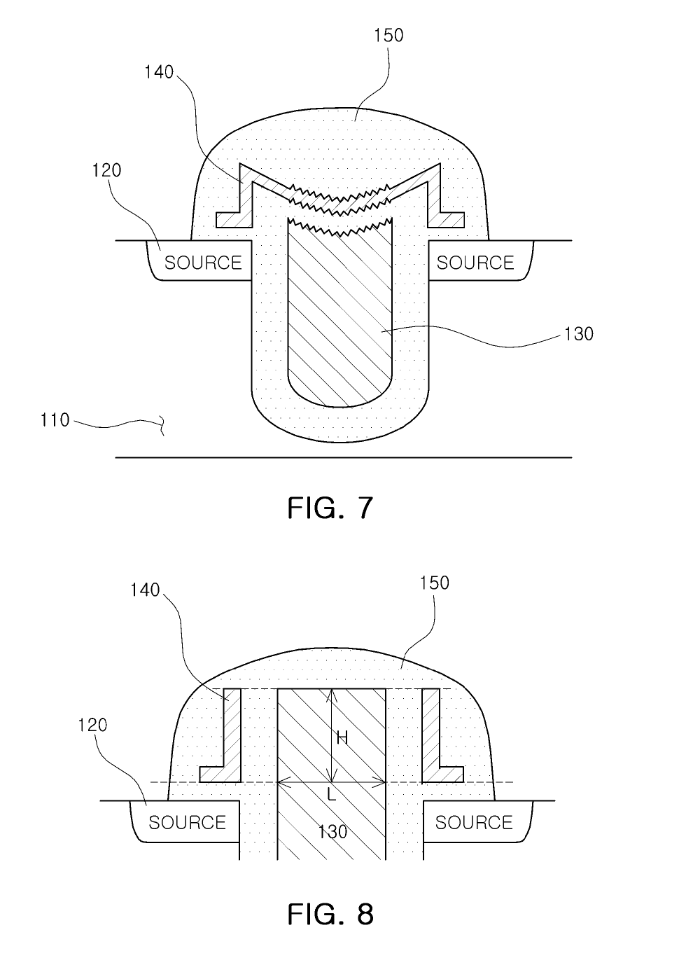

FIG. 7 shows a problem that may occur at the time of manufacturing a semiconductor device.

Referring to FIGS. 6 and 7, there may be prepared the semiconductor body 110 having a predetermined volume; the source 120 formed on the upper surface of the semiconductor body 110; the gate 130 formed in the groove of the semiconductor body 120, which has a predetermined depth, and having the protrusion region 131 protruded upwardly of the upper surface of the semiconductor body 110; and the electrode 140 covering the protrusion region 131 of the gate 130 (S1). Here, since the upper surface of the protrusion region 131 of the gate 130 and a surface of the electrode 140 covering the upper surface of the protrusion region 131 are rough, it is difficult to precisely control the capacitance between the electrode 140 and the gate 130.

Therefore, the capacitance between the electrode 140 and the gate 130 may be controlled by grinding and removing a portion of the electrode 140, which covers the upper surface of the protrusion region 131 of the gate 130, and regulating the height of the protrusion region 131.

FIG. 8 is a partial enlarged view of the semiconductor device according to the embodiment of the present invention.

Referring to FIG. 8, the protrusion region 131 of the gate 130 may have a height (H) and a width (L).

Here, the height (H) of the protrusion region 131 may denote a length from the upper surface of the protrusion region 131 to a portion of the lateral surface of the protrusion region 131 facing the electrode 140.

As described above, the height (H) of the protrusion region 131 may be regulated to control the capacitance between the electrode 140 and the gate 130, and here, the height (H) of the protrusion region 131 may be regulated in the first operation (S1) of FIG. 6.

The lateral surface of the protrusion region 131 forms capacitance with the facing electrode, and the capacitance may be controlled based on the length and area of the facing electrode 140, the distance between the electrode and the lateral surface of the protrusion region 131, or the like.

For example, the capacitance may be increased, as the distance between the electrode 140 and the lateral surface of the protrusion region 131 is shortened, or the height of the protrusion region 131 or the length of the electrode 140 is increased.

Therefore, the gate-source capacitance can be improved without an increase in a width of the semiconductor device 100.

As shown in FIG. 6, a plurality of semiconductor devices may be arranged on a semiconductor substrate. When the width of the semiconductor device is increased in order to improve the gate-source capacitance, a distance between the semiconductor devices becomes narrow since the semiconductor substrate has a limited area. Therefore, since at least a predetermined distance between the semiconductor devices should be maintained in manufacturing of the semiconductor devices, it is difficult to manufacture a desired number of semiconductor devices or obtain good-quality semiconductor devices.

Meanwhile, the height of the protrusion region 131 may be set to at least 0.5 times greater than the width thereof, and thus, the gate-source capacitance can be further increased without an increase in the width of the semiconductor device, as compared with an amount of the gate-source capacitance increased by maintaining at least a predetermined distance between the semiconductor devices and increasing the width of the semiconductor device.

As described above, according to the embodiments of the present invention, the shoot-through phenomenon can be removed without an increase in the width of the semiconductor device, by forming the capacitance between the electrode and the lateral surface of the protrusion region of the gate and then altering the height of the protrusion region to increase the gate-source capacitance without an increase in the width of the semiconductor device. Here, since the width of the semiconductor device is not increased regardless of an increase in the gate-source capacitance, a desired number of semiconductor devices can be obtained on the semiconductor substrate having a limited area.

Further, the MOS FET is given as an example of the semiconductor device 100 as described above, but the gate 130 having the protrusion region and the electrode 140 forming the capacitance together with the lateral surface of the protrusion region may also be applied to an insulated gate bipolar transistor (IGBT).

As set forth above, according to embodiments of the present invention, a shoot-through phenomenon can be removed even without an increase in a width of a semiconductor device, by forming capacitance between an electrode connected to a source and a lateral surface of a protrusion region of a gate and altering a height of the protrusion region to increase gate-source capacitance without an increase in the width of the semiconductor device.

While the present invention has been shown and described in connection with the embodiments, it will be apparent to those skilled in the art that modifications and variations can be made without departing from the spirit and scope of the invention as defined by the appended claims.

What is claimed is:

1. A semiconductor device, comprising:
a semiconductor body having a predetermined volume;
a source formed on an upper surface of the semiconductor body;
a gate formed in a groove of the semiconductor body and having a protrusion region protruded upwardly of the upper surface of the semiconductor body, the groove having a predetermined depth and the protrusion region having a protrusion height altered depending on a level of capacitance to be set; and
an electrode electrically connected to the source to form capacitance together with a lateral surface of the protrusion region of the gate.

2. The semiconductor device of claim 1, further comprising a drain formed on a lower surface of the semiconductor body.

3. The semiconductor device of claim 1, further comprising a dielectric layer formed between the protrusion region of the gate and the electrode.

4. The semiconductor device of claim 2, wherein the source, the drain, and the gate constitute a metal-oxide-semiconductor field-effect transistor (MOS FET).

5. The semiconductor device of claim 1, wherein the protrusion height of the protrusion region of the gate is at least 0.5 times greater than a width thereof.

6. A method of manufacturing a semiconductor device, the method comprising:
preparing a semiconductor body having a predetermined volume, a source formed on an upper surface of the semiconductor body, a gate formed in a groove of the semiconductor body and having a protrusion region protruded upwardly of the upper surface of the semiconductor body, the groove having a predetermined depth, and an electrode covering the protrusion region of the gate;
grinding and removing a portion of the electrode disposed to cover an upper surface of the protrusion region of the gate; and
depositing an oxide film on the upper surface of the protrusion region of the gate.

7. The method of claim 6, wherein the preparing of the electrode comprises setting a desired capacitance level by altering a protrusion height of the protrusion region of the gate and a length of the electrode facing a lateral surface of the protrusion region.

8. The method of claim 6, wherein the preparing of the electrode comprises forming a drain on a lower surface of the semiconductor body.

9. The method of claim 6, wherein the preparing of the electrode comprises electrically connecting the electrode to the source.

10. The method of claim 6, wherein the preparing of the electrode comprises forming a dielectric layer between the protrusion region of the gate and the electrode.

11. The method of claim 8, wherein the source, the drain, and the gate constitute a metal-oxide-semiconductor field-effect transistor (MOS FET).

12. The method of claim 7, wherein the protrusion height of the protrusion region of the gate is at least 0.5 times greater than a width thereof.
